(19) United States
(12) Patent Application Publication
(10) Pub. No.: US 2026/0107620 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Ji Seong YANG, Yongin-si (KR); Boram LEE, Yongin-si (KR); Seon Uk LEE, Yongin-si (KR); Song Ee LEE, Yongin-si (KR); Tae Hyung HWANG, Yongin-si (KR)

(21) Appl. No.: 19/266,502

(22) Filed: Jul. 11, 2025

(30) Foreign Application Priority Data
Oct. 10, 2024 (KR) 10-2024-0137660

(51) Int. Cl. H10H 29/855; H10H 29/85; H10H 29/851; H10H 29/853

(52) U.S. Cl. CPC H10H 29/8552; H10H 29/8514; H10H 29/8517; H10H 29/853

(57) ABSTRACT

A display device may include a lower substrate, a light emitting layer on the lower substrate, an encapsulating layer on the light emitting layer, a light blocking layer on the encapsulating layer and having a plurality of openings, a color conversion layer on the encapsulating layer and overlapping the plurality of openings, a spacer on the light blocking layer, an insulating layer on the light blocking layer and the color conversion layer and contacting the spacer, and a color filter layer on the insulating layer. A refractive index of the spacer may be smaller than a refractive index of the insulating layer.

### CROSS-REFERENCE TO RELATED APPLICATION

The present application claims priority to and the benefit of Korean Patent Application No. 10-2024-0137660, filed on Oct. 10, 2024, in the Korean Intellectual Property Office, the entire content of which is incorporated herein by reference.

### BACKGROUND

### 1. Field

Embodiments of the present disclosure described herein are related to a display device, and for example, to a display device including light emitting diodes.

### 2. Description of the Related Art

Light emitting display devices, which display images by controlling the brightness of light emitting elements, and liquid crystal display devices, which display images by controlling the transmittance of a liquid crystal layer, are used as display devices. Unlike liquid crystal displays, light emitting displays do not require a separate light source such as a backlight, which allows the display device to be reduced in thickness and/or weight. In addition, light emitting display devices may exhibit high-quality characteristics such as relatively low power consumption, relatively high brightness, and/or relatively high response speed.

A light emitting display device may include a display area corresponding to a screen displaying an image, with pixels may be arranged in the display area. The pixels may be implemented by light emitting diodes. A light emitting diode may include a light emitting layer positioned between two electrodes. One of the two electrodes may be a pixel electrode individually provided for each pixel, and the other may be a common electrode commonly provided to multiple pixels.

The information disclosed in this Background section is intended to enhance understanding of the background of the disclosure and therefore it may contain information that does not constitute prior art.

### SUMMARY

Aspects according to one or more embodiments of the present disclosure are directed toward a display device with enhanced (e.g., improved) light efficiency.

Aspects according to one or more embodiments of the present disclosure are directed toward a display device with improved resolution.

Additional aspects will be set forth in part in the description which follows and, in part, will be apparent from the description, or may be learned by practice of the presented embodiments of the disclosure.

A display device according to one or more embodiments includes a lower substrate, a light emitting layer on the lower substrate, an encapsulating layer on the light emitting layer, a light blocking layer on the encapsulating layer and having a plurality of openings, a color conversion layer on the encapsulating layer and overlapping the plurality of openings, a spacer on the light blocking layer, an insulating layer on the light blocking layer and the color conversion layer and contacting the spacer, and a color filter layer on the insulating layer. A refractive index of the spacer is smaller than a refractive index of the insulating layer.

In one or more embodiments, the color conversion layers may be between adjacent spacers.

In one or more embodiments, the spacers may be around (e.g., surround) the color conversion layer in a plane parallel to the lower substrate (e.g., in a plan view of the lower substrate).

In one or more embodiments, in the spacer on the light blocking layer between a pair of openings adjacent to each other in a first direction among the plurality of openings, the spacer may include a contact surface that contacts an upper surface of the light blocking layer, and a minimum width of the upper surface of the light blocking layer may be greater than or equal to a minimum width of the contact surface of the spacer.

In one or more embodiments, a ratio of the minimum width of the contact surface of the spacer to the minimum width of the upper surface of the light blocking layer may be 0.5 to 1.

In one or more embodiments, a center of the light blocking layer between the pair of openings adjacent to each other in the first direction may be aligned with a center of the spacer on the light blocking layer between the pair of openings adjacent to in the first direction.

In one or more embodiments, the light blocking layer and the spacer may extend in a second direction intersecting the first direction, and a pair of edges extending in the second direction of the contact surface of the spacer and may overlap a pair of edges extending in the second direction of the upper surface of the light blocking layer.

In one or more embodiments, the light blocking layer and the spacer may extend in a second direction intersecting the first direction, and a center line extending in the second direction of the contact surface of the spacer may be offset from a center line extending in the second direction of the upper surface of the light blocking layer.

In one or more embodiments, the contact surface of the spacer and the upper surface of the light blocking layer may have one edge that extends in the second direction and are aligned with each other in the second direction.

In one or more embodiments, the spacer may include a contact surface that contacts the light blocking layer and a surface that protrudes from the light blocking layer, and the surface of the spacer may include a curved surface.

In one or more embodiments, the spacer may include a contact surface that contacts the light blocking layer and a surface that protrudes from the light blocking layer, and the surface of the spacer may include a flat surface.

In one or more embodiments, the refractive index of the spacer may be in the range of 0.5 to 1.5.

In one or more embodiments, the spacer and the color filter layer may be spaced and/or apart (e.g., spaced apart or separated) from each other with the insulating layer therebetween.

A display device according to one or more embodiments includes a lower substrate, a light emitting layer on the lower substrate, an encapsulating layer on the light emitting layer, a light blocking layer on the encapsulating layer and having a plurality of openings including a first opening, a second opening, and a third opening, a color conversion layer on the encapsulating layer and including a first color conversion pattern overlapping the first opening, a second color conversion pattern overlapping the second opening, and a third color conversion pattern overlapping the third opening, a spacer on the light blocking layer, an insulating layer on the light blocking layer and the color conversion layer, and a color filter layer on the insulating layer. A refractive index of the spacer is smaller than a refractive index of the insulating layer.

In one or more embodiments, light may be emitted from the light emitting layer, and the first color conversion pattern, the second color conversion pattern, and the third color conversion pattern may each convert the light into different colors.

In one or more embodiments, the spacer may be around (e.g., surround) all of the first color conversion pattern, the second color conversion pattern, and the third color conversion pattern on a plane.

In one or more embodiments, the spacer may include spacer units separated from each other, and the spacer units may be spaced and/or apart (e.g., spaced apart or separated) from each other to be around (e.g., surround) the first color conversion pattern, the second color conversion pattern, and the third color conversion pattern in a plane.

In one or more embodiments, the spacer unit may include a first spacer unit between the first color conversion pattern and the second color conversion pattern, a second spacer unit between the second color conversion pattern and the third color conversion pattern, and a third spacer unit between the first color conversion pattern and the third color conversion pattern, and at least two selected from among a number of the first spacer units, a number of the second spacer units, and a number of the third spacer units may be different from each other.

In one or more embodiments, the spacer unit may include a contact surface that contacts the light blocking layer and a surface that protrudes from the light blocking layer, and the surface of the spacer may include a curved surface.

In one or more embodiments, the spacer may include a first sub-spacer between the first color conversion pattern and the second color conversion pattern, a second sub-spacer between the second color conversion pattern and the third color conversion pattern, and a third sub-spacer between the first color conversion pattern and the third color conversion pattern.

In one or more embodiments, the display device may include a lower substrate, a light emitting layer on the lower substrate, an encapsulating layer on the light emitting layer, a light blocking layer on the encapsulating layer and having a plurality of openings, a color conversion layer on the encapsulating layer and overlapping the plurality of openings, a spacer on the light blocking layer, an insulating layer on the light blocking layer and the color conversion layer and in contact with the spacer, and a color filter layer on the insulating layer.

In one or more embodiments, a refractive index of the spacer is smaller than a refractive index of the insulating layer.

In one or more embodiments, the light blocking layer may include a first opening, a second opening, and a third opening, and the color conversion layer may include a first color conversion pattern overlapping the first opening, a second color conversion pattern overlapping the second opening, and a third color conversion pattern overlapping the third opening.

In one or more embodiments, a color conversion layer may be included in the display device to convert the wavelength of light provided from the light emitting element. Additionally, color clarity may be improved through the color filter layer. For example, even if light of one color is emitted, the color of the light may be converted through a color conversion layer, and the clarity may be improved through a color filter layer. However, some light may be absorbed by the color filter layer, and/or the like, and may not be emitted.

An electronic device may include a display device according to one or more embodiments.

According to one or more embodiments, the amount of light emitted through the color conversion layer may be increased. Accordingly, the light efficiency may be improved, and the resolution of the display device may be enhanced.

Additionally, because additional materials such as masks are not desired or required, the process convenience may be improved.

For example, a color conversion layer may be included in the display device to convert the wavelength of light provided from the light-emitting element. Additionally, color clarity may be improved through the color filter layer. For example, even if light of one color is emitted, the color of the light may be converted through a color conversion layer, and the clarity may be improved through a color filter layer. However, some light may be absorbed by the color filter layer, and/or the like, and may not be emitted. The color conversion layer composed of materials that can absorb light of one wavelength and re-emit it at a different wavelength, thereby enhancing the color gamut and accuracy of the display. This process can significantly improve the visual experience by providing more vibrant and accurate colors. According to one or more embodiments, the amount of light emitted through the color conversion layer may be increased. Accordingly, the light efficiency may be improved, and the resolution of the display device may be enhanced. By further enhancing the materials and structure of the color conversion layer, it is possible to further increase the amount of light that is converted and emitted, thereby further increasing the overall brightness and efficiency of the display. This can lead to displays that are not only more energy-efficient but also capable of producing higher resolution images with greater detail and clarity. Additionally, because additional materials such as masks are not desired or required, the process convenience may be improved. This simplification in the manufacturing process can reduce production costs and time, making the technology more accessible and scalable for various applications. Also, for example, an electronic device may include the display device. This electronic device can be any device that utilizes a display for visual output, such as smartphones, tablets, televisions, and/or monitors. The integration of the display device into various electronic devices can enhance the visual performance and user experience by providing clearer, brighter, and more energy-efficient displays. The improved light efficiency and resolution of the display device can contribute to longer battery life and better overall performance of the electronic device.

### BRIEF DESCRIPTION OF THE DRAWINGS

FIG. 1 is a schematic plan view of a display device according to one or more embodiments.

FIG. 2 is a schematic cross-sectional view of a display area in a display device according to one or more embodiments.

FIGS. 3-6 are schematic cross-sectional views each being of an area corresponding to one pixel of a display area in a display device according to one or more embodiments.

FIGS. 7-11 are schematic plan views each being of a display area in a display device according to one or more embodiments.

FIG. 12 is a block diagram of an electronic device according to one or more embodiments.

FIG. 13 is a schematic diagram of electronic devices according to one or more embodiments.

### DETAILED DESCRIPTION

Hereinafter, one or more suitable embodiments of the present disclosure will be described in more detail with reference to the attached drawings so that a person having ordinary skill in the art to which the present disclosure pertains may easily implement the present disclosure. The present disclosure may be embodied in many different forms and is not limited to one or more embodiments described herein.

In order to clearly explain the present disclosure, parts irrelevant to the description are not provided, and the same reference numerals are used for substantially identical or similar components throughout the specification.

In addition, the size and thickness of each component shown in the drawings are arbitrarily shown for convenience of explanation, so the present disclosure is not necessarily limited to that which is shown. In the drawings, the thicknesses of layers, films, panels, regions, and/or the like, are exaggerated for clarity. And in the drawings, for convenience of explanation, the thickness of some layers and areas is exaggerated.

In the present specification, “including A or B”, “A and/or B”, etc., represents A or B, or A and B.

As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Also, if (e.g., when) it is said that a part, such as a layer, membrane, region, or plate, is “over” or “on” another part, this includes not only cases where it is “directly over” the other part, but also cases where there are other parts in between. In contrast, if (e.g., when) an element is referred to as being “directly on” another element, there are no intervening elements present. Also, being “above” or “on” a reference part refers to being positioned above or below the reference part, and does not necessarily refer to being positioned “above” or “on” it in the opposite direction of gravity.

Additionally, throughout the specification, whenever a part is said to “include” a component, this does not refer to that it excludes other components, but rather that it may include other components, unless otherwise specifically stated.

Additionally, throughout the specification, if (e.g., when) reference is made to “in a plan view,” it refers to if (e.g., when) the target portion is viewed from above, and if (e.g., when) reference is made to “in a cross-section,” it refers to if (e.g., when) the target portion is viewed from the side in a cross-section cut vertically.

The singular forms “a,” “an,” and “the” as used herein are intended to include the plural forms as well unless the context clearly indicates otherwise.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

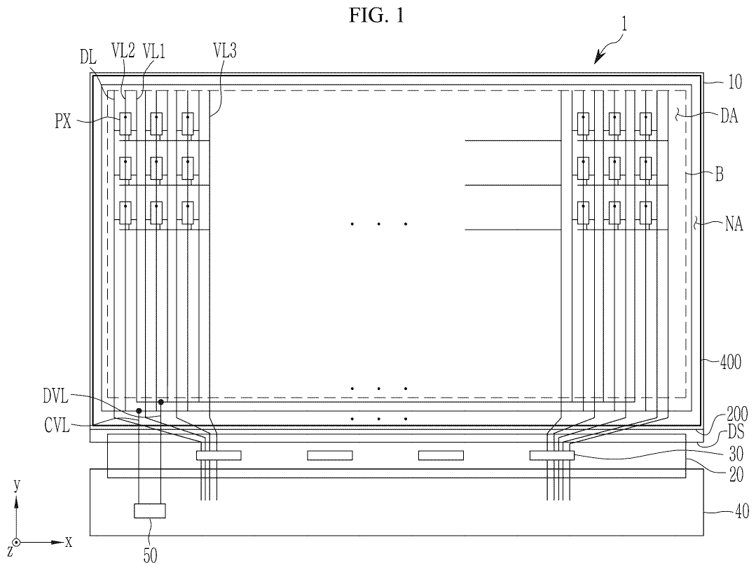

FIG. 1 is a schematic plan view of a display device according to one or more embodiments.

Referring to FIG. 1, the display device 1 may include a display panel 10, a flexible printed circuit board 20, a driving integrated circuit chip 30, a printed circuit board 40, a power module 50, and/or the like.

The display panel 10 may include a display area DA corresponding to a screen that displays an image, and a non-display area NA in which circuits and wires for generating and transmitting one or more suitable signals applied to the display area DA are arranged. The non-display area NA may be adjacent to the display area DA or may be around (e.g., surround) the display area DA. In FIG. 1, the inner and outer areas of the boundary line B may be the display area DA and the non-display area NA, respectively.

The display panel 10 may include a display part DS and a color filter part 200. The display part DS may include a base layer and a color conversion portion. The display part DS and the color filter part 200 may be joined by a sealant 400 positioned around the edge of the display panel 10 between the display part DS and the color filter part 200. The color filter part 200 may entirely overlap the display part DS, but the display part DS may include an area not covered by the color filter part 200 for connection or bonding of the flexible printed circuit board 20. The display part DS may include a pad part for connection or bonding of a flexible printed circuit board 20. The display part DS may include an area where the pad part is positioned so as to expose the pad part to the outside. For example, the color filter part 200 at the lower end of the display panel 10 may be formed shorter than the display part DS, and an area where the color filter part 200 and the display part DS do not overlap may be provided as an area where the pad part is positioned. The display part DS and the color filter part 200 may each include areas corresponding to the display area DA and the non-display area NA of the display panel 10.

The display area DA of the display panel 10 may include pixels PX positioned in a matrix. Additionally, a data line DL for transmitting a data voltage, a driving voltage line VL1 for transmitting a driving voltage, a common voltage line VL2 for transmitting a common voltage, and an initialization voltage line VL3 for transmitting an initialization voltage may be positioned in the display area DA. The driving voltage line VL1, the common voltage line VL2, and the initialization voltage line VL3 may extend in a longitudinal direction y. At least one of the driving voltage line VL1, the common voltage line VL2, or the initialization voltage line VL3 may be connected to an auxiliary voltage line extending in a width direction x.

The display panel 10 may have driving voltage transmission lines DVL connected to driving voltage lines VL1 and common voltage transmission lines CVL positioned in the non-display area NA.

The driving voltage transmission line DVL and the common voltage transmission line CVL may each include portions extending approximately in the longitudinal direction y and portions extending approximately in the width direction x. For example, the driving voltage transmission line DVL and the common voltage transmission line CVL may each include portions extending in the longitudinal direction y and portions extending in the width direction x. The common voltage line CVL may be positioned to be around (e.g., surround) the display area DA.

The flexible printed circuit board 20 may have one end connected or bonded to the display part DS of the display panel 10, and the other end connected or bonded to the printed circuit board 40. The flexible printed circuit board 20 may have a drive integrated circuit chip 30 including a data drive unit positioned thereon.

The power module 50 that generates a power voltage such as a driving voltage, a common voltage, and/or the like may be positioned on the printed circuit board 40. The power module 50 may include (e.g., may be provided in the form of) an integrated circuit chip. A signal control unit that controls the data driving unit and the gate driving unit may be positioned on the printed circuit board 40.

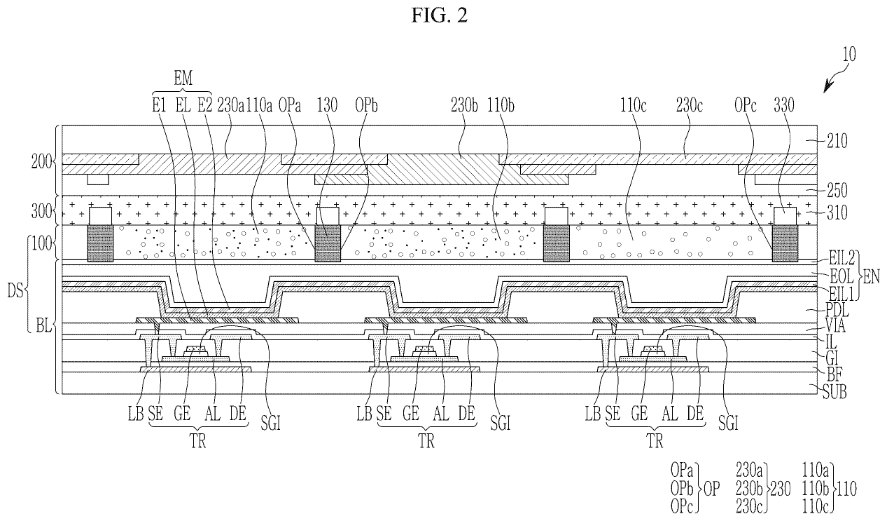

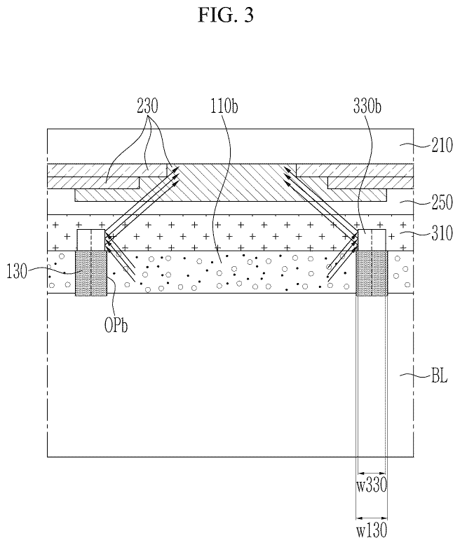

FIG. 2 is a cross-sectional view schematically illustrating a portion of a display area in a display device according to one or more embodiments. FIG. 3 is a schematic cross-sectional view of an area corresponding to one pixel of a display area in a display device according to one or more embodiments. Although FIG. 3 illustrates an enlarged view of the area of a second color conversion pattern 110b and a second color filter pattern 230b of FIG. 2, the structure described with reference to FIG. 3 may be substantially equally or equally applied to the area of a first color conversion pattern 110a and a first color filter pattern 230a, and the area of a third color conversion pattern 110c and a third color filter pattern 230c.

Referring to FIGS. 2 and 3, the display panel 10 includes a base layer BL, a color conversion part 100, a color filter part 200, and a filling part 300. The base layer BL and the color conversion part 100 may constitute a display part DS. The filling part 300 may be positioned between the display part DS and the color filter part 200.

The base layer BL may include a lower substrate SUB. The lower substrate SUB may include a material having rigid properties, such as glass, or a material having flexible properties, such as plastic. For example, the lower substrate SUB may be a glass substrate. The lower substrate SUB may include a polymer material such as polyimide, polyamide, or polyethylene terephthalate.

The base layer BL may include a buffer layer BF positioned on the lower substrate SUB. The buffer layer BF may block or reduce impurities from the lower substrate SUB if (e.g., when) forming a semiconductor layer AL, thereby improving the characteristics of the semiconductor layer, and may also alleviate stress on the semiconductor layer AL by flattening the surface of the lower substrate SUB. The buffer layer BF may be an inorganic insulating layer that may include an inorganic insulating material such as silicon nitride SiNₓ, silicon oxide SiOₓ, or silicon oxynitride SiOₓN_{y}, and may have a single-layer structure or a multi-layer structure.

A first conductive layer, which may include a light blocking pattern LB, and/or the like, may be positioned on the lower substrate SUB. For example, the first conductive layer that may include the light blocking pattern LB, and/or the like, may be positioned between the lower substrate SUB and the buffer layer BF. Components included in the first conductive layer may include (e.g., may be formed from) the same material in the same (e.g., substantially the same) process. For example, a conductive layer may be arranged and patterned on the substrate SUB to form data lines DL, driving voltage lines VL1, common voltage lines VL2, initialization voltage lines VL3, and light blocking patterns LB.

A transistor TR may be positioned on the lower substrate SUB. For example, the transistor TR may be positioned on the buffer layer BF positioned on the lower substrate SUB.

The semiconductor layer AL of the transistor TR may be positioned on the lower substrate SUB. The semiconductor layer AL may include a first semiconductor region, a second semiconductor region, and a channel region positioned between the first semiconductor region and the second semiconductor region. The semiconductor layer AL may include any one of amorphous silicon, polycrystalline silicon, or oxide semiconductor. For example, the semiconductor layer AL may include low-temperature polycrystalline silicon LTPS or an oxide semiconductor material including at least one of zinc (Zn), indium (In), gallium (Ga), or tin (Sn). For example, the semiconductor layer AL may include indium gallium zinc oxide (IGZO). The light blocking pattern LB may prevent or reduce external light from reaching the semiconductor layer AL of the transistor TR and thereby prevent or reduce the characteristics of the semiconductor layer AL from deteriorating.

A first gate insulating layer SGI may be positioned on the semiconductor layer AL. The first gate insulating layer SGI may include an inorganic insulating material such as silicon nitride, silicon oxide, or silicon oxynitride. The first gate insulating layer SGI may have a single-layer structure or a multi-layer structure.

A gate conductive layer, which may include a gate electrode GE of a transistor TR, may be positioned on the first gate insulating layer SGI. The gate conductive layer may include molybdenum (Mo), aluminum (Al), copper (Cu), titanium (Ti), and/or the like, and may have a single-layer structure or a multi-layer structure.

A second gate insulating layer GI may be positioned on the gate conductive layer. The second gate insulating layer GI may include an inorganic insulating material such as silicon nitride, silicon oxide, or silicon oxynitride. The second gate insulating layer GI may have a single-layer structure or a multi-layer structure.

An interlayer insulating layer IL may be positioned on the second gate insulating layer GI. The interlayer insulating layer IL may include an inorganic insulating material such as silicon nitride, silicon oxide, or silicon oxynitride. The interlayer insulation IL may be a single-layer structure or a multi-layer structure. An additional gate conductive layer may be positioned above the interlayer insulating layer IL.

A data conductive layer, which may include a first lower electrode SE and a second lower electrode DE of a transistor TR, may be positioned on the interlayer insulating layer IL. The first lower electrode SE and the second lower electrode DE may be connected to the first semiconductor region and the second semiconductor region of the semiconductor layer AL, respectively, through contact holes formed in the insulating layers (SGI, GI, IL). The first lower electrode SE and the second lower electrode DE may be such that one selected from among the first lower electrode SE and the second lower electrode DE may be a source electrode and the other may be a drain electrode. The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and/or the like, and may have a single-layer structure or a multi-layer structure. For example, the data conductive layer may include a lower layer including a refractory metal, such as molybdenum, chromium, tantalum, or titanium; a middle layer including a low-resistivity metal, such as aluminum, copper, or silver; and an upper layer including a refractory metal. For example, the data conductive layer may have a triple-layer structure such as titanium (Ti)/aluminum (Al)/titanium (Ti).

A planarization layer VIA may be positioned above the data conductive layer. For example, the planarization layer VIA may be positioned on the transistor TR including the semiconductor layer AL, the gate electrode GE, the first lower electrode SE, and the second lower electrode DE. The planarization layer VIA may be positioned over the second gate insulating layer GI.

The planarization layer VIA may include an organic insulating material such as a general-purpose polymer such as poly(methyl methacrylate) or polystyrene, a polymer derivative having a phenolic group, an acrylic polymer, an imide polymer (e.g., polyimide), or a siloxane polymer.

A light emitting element EM may be positioned on the planarization layer VIA. The light emitting element EM may include a pixel electrode E1, a light emitting layer EL, and a common electrode E2. The light emitting element EM is positioned on the planarization layer VIA and may be electrically connected to the transistor TR.

The light emitting element EM may include the pixel electrode E1. The pixel electrode E1 may be positioned on the planarizing layer VIA positioned on the lower substrate SUB. The pixel electrode E1 may be an anode of the light emitting element EM. The pixel electrode E1 may be electrically connected to the transistor TR. For example, the pixel electrode E1 may be connected to the second lower electrode DE of the transistor TR through a contact hole formed in the planarization layer VIA.

The pixel electrode E1 may include (e.g., may be formed of) a reflective conductive material or a semi-transparent conductive material, or may include (e.g., may be formed of) a transparent conductive material. The pixel electrode E1 may include a metal or metal alloy such as lithium (Li), calcium (Ca), aluminum (Al), silver (Ag), magnesium (Mg), or gold (Au). The pixel electrode E1 may be multilayered, and may have a triple-layer structure such as indium tin oxide (ITO)/silver (Ag)/ITO, for example.

A pixel defining layer PDL having an opening overlapping the pixel electrode E1 may be positioned above the planarization layer VIA. The pixel electrode E1 may be positioned in an opening in the pixel defining layer PDL. The opening may correspond to the light emitting area of the light emitting element EM.

The pixel defining layer PDL may include organic insulating materials such as general-purpose polymers such as polymethyl methacrylate and polystyrene, polymer derivatives having phenolic groups, acrylic polymers, and imide polymers, and siloxane polymers.

An intermediate layer may be positioned on at least one of the pixel electrode E1 or the pixel defining layer PDL. The intermediate layer may include at least one of the light emitting layer EL or a functional layer. For example, the intermediate layer including the light emitting layer EL and a functional layer may be positioned on the pixel electrode E1 and the pixel defining layer PDL positioned on the lower substrate SUB.

The light emitting layer EL is a layer in which electric-to-light conversion takes place through a combination of electrons and holes, and may include at least one of an organic material or an inorganic material that emits light of a set or predetermined color. The light emitting layer EL may be positioned within the opening of the pixel defining layer PDL and may overlap with the pixel electrode E1. A portion of the light emitting layer EL may be positioned over the pixel defining layer PDL. The light emitting layer EL may include the organic light emitting diode or the inorganic light emitting diode.

The functional layer may include at least one of a hole injection layer, a hole transport layer, an electron transport layer, or an electron injection layer. The functional layer may include a first functional layer positioned between the pixel electrode E1 and the light emitting layer EL, and a second functional layer positioned between the light emitting layer EL and the common electrode E2. The first functional layer may include at least one of a hole injection layer or a hole transport layer. The second functional layer may include at least one of an electron transport layer or an electron injection layer. The functional layer may be positioned or extended across the entire display area DA as described with reference to FIG. 1. The functional layer may be positioned in the opening of the pixel defining layer PDL. The functional layer may be positioned outside the opening of the pixel defining layer PDL.

The common electrode E2 may be positioned on the intermediate layer including the light emitting layer EL and the functional layer. The pixel electrode E1 may be an anode of the light emitting element EM, and the common electrode E2 may be a cathode of the light emitting element EM. The common electrode E2 may be positioned or extended across the entire display area DA as described with reference to FIG. 1.

The common electrode E2 may include a metal or metal alloy having a low work function, such as calcium (Ca), barium (Ba), magnesium (Mg), aluminum (Al), or silver (Ag). For example, light transparency may be achieved by forming a thin layer of a metal or metal alloy with low work function. The common electrode E2 may include a transparent conductive oxide such as ITO or indium zinc oxide IZO.

The common electrode E2 may form the light emitting element EM together with the pixel electrode E1 and the light emitting layer EL. The light emitting element EM may include a functional layer including a first functional layer and a second functional layer.

A first capping layer may be positioned on the common electrode E2. The first capping layer may improve optical efficiency by adjusting the refractive index.

An encapsulating layer EN may be positioned on the first capping layer. The encapsulating layer EN may encapsulate a light emitting element EM including a light emitting layer EL to prevent or reduce moisture or oxygen from penetrating from the outside. The encapsulation layer EN may be a thin-film encapsulation layer including one or more inorganic layers EIL1, EIL2 and one or more organic layers EOL.

The color conversion part 100 may be positioned on the base layer BL. For example, a color conversion part 100 may be positioned on the encapsulation layer EN of the base layer BL. A light blocking layer 130 of the color conversion part 100 may be positioned on the encapsulating layer EN of the base layer BL.

The light blocking layer 130 may be positioned on the encapsulating layer EN. The blocking layer 130 may also be referred to as a bank. The blocking layer 130 may be positioned in the display area DA described with reference to FIG. 1. The blocking layer 130 may be positioned at the boundary of the pixels PX. The blocking layer 130 may partition a pixel area. The light blocking layer 130 may include an organic insulating material such as acrylic polymer, imide polymer, or amide polymer. The blocking layer 130 may be a black blocking layer containing a colored pigment such as a black pigment, but may also be transparent.

The light blocking layer 130 positioned on the encapsulating layer EN may form a plurality of openings OP. The plurality of openings OP may be defined as holes formed by the light blocking layer 130. For example, the plurality of openings OP may be defined as areas exposed from the light blocking layer 130 in the color conversion part 100. For example, the plurality of openings OP may be defined from the sides of the blocking layer 130. The plurality of openings OP may expose the encapsulating layer EN from the blocking layer 130. The plurality of openings OP may be repeated with the blocking layer 130 interposed therebetween.

The plurality of openings OP may include a first opening OPa, a second opening OPb, and a third opening OPc. For example, the light blocking layer 130 may form a plurality of openings OP including the first opening OPa, the second opening OPb, and the third opening OPc.

A color conversion layer 110 may be positioned on the encapsulation layer EN. The color conversion layer 110 may overlap with a plurality of openings OP formed by the light blocking layer 130. For example, the color conversion layer 110 may overlap with a plurality of openings OP formed by the light blocking layer 130 on the encapsulating layer EN.

The color conversion layer 110 may include a first color conversion pattern 110a, a second color conversion pattern 110b, and a third color conversion pattern 110c. The first color conversion pattern 110a, the second color conversion pattern 110b, and the third color conversion pattern 110c may all be positioned within a space defined by the light blocking layer 130 (for example, an opening OP formed by the light blocking layer 130). The color conversion layer 110 may include the first color conversion pattern 110a overlapping with the first opening OPa, the second color conversion pattern 110b overlapping with the second opening OPb, and the third color conversion pattern 110c overlapping with the third opening OPc.

The first color conversion pattern 110a may overlap with the light emitting area of the light emitting element EM. The first color conversion pattern 110a may convert light incident from the light emitting layer EL of the light emitting element EM into light of the first wavelength. The light of the first wavelength may be red light having a maximum emission peak wavelength of about 600 nm to about 650 nm, or about 620 nm to about 650 nm. For example, the first color conversion pattern 110a may convert light incident from the light emitting element EM into red light.

The second color conversion pattern 110b may overlap with the light emitting area of the light emitting element EM. The second color conversion pattern 110b may convert light incident from the light emitting layer EL of the light emitting element EM into light of a second wavelength. The light of the second wavelength may be green light having a maximum emission peak wavelength of about 500 nm to about 550 nm, or about 510 nm to about 550 nm. For example, the second color conversion pattern 110b may convert light incident from the light emitting element EM into green light.

The third color conversion pattern 110c may overlap with the light emitting area of the light emitting element EM. The third color conversion pattern 110c may convert light incident from the light emitting layer EL of the light emitting element EM into light of a third wavelength. The third wavelength light may be blue light having a maximum emission peak wavelength of about 380 nm to about 480 nm, or about 430 nm to about 460 nm. For example, the third color conversion pattern 110c may convert light incident from the light emitting element EM into blue light.

The third color conversion pattern 110c may also be referred to as a transmission pattern. For example, the light emitting element EM may be configured to emit blue light having a maximum emission peak wavelength of about 380 nm to about 480 nm, or about 430 nm to about 460 nm. The third color conversion pattern 110c may be configured to transmit blue light incident from the light emitting element EM.

The first color conversion pattern 110a, the second color conversion pattern 110b, and the third color conversion pattern 110c may include first quantum dots, second quantum dots, and third quantum dots, respectively. Light incident on the first color conversion pattern 110a may be converted into light of a first wavelength by the first quantum dots and emitted. Light incident on the second color conversion pattern 110b may be converted into light of a second wavelength by the second quantum dots and emitted. Light incident on the third color conversion pattern 110c may be converted into light of a third wavelength by the third quantum dots and emitted.

When the light emitted from the light emitting element EM is blue light, the first color conversion pattern 110a and the second color conversion pattern 110b may include first quantum dots and second quantum dots, respectively. Light incident on the first color conversion pattern 110a may be converted into light of a first wavelength by the first quantum dots and emitted. Light incident on the second color conversion pattern 110b may be converted into light of a second wavelength by the second quantum dots and emitted. The wavelength of light incident on the third color conversion pattern 110c may not be converted.

The first color conversion pattern 110a, the second color conversion pattern 110b, and the third color conversion pattern 110c may include scatterers. The scatterers may improve light efficiency by scattering light incident on the first color conversion pattern 110a, the second color conversion pattern 110b, and the third color conversion pattern 110c.

The first quantum dot, the second quantum dot, and the third quantum dot (hereinafter, also referred to as a semiconductor nanocrystal) may each independently include a group II-VI compound, a group III-V compound, a group IV-VI compound, a group IV element or compound, a group I-III-VI compound, a group II-III-VI compound, a group I-II-IV-VI compound, and/or a (e.g., any suitable) combination thereof.

The II-VI group compound is a binary compound selected from the group consisting of CdSe, CdTe, ZnS, ZnSe, ZnTe, ZnO, HgS, HgSe, HgTe, MgSe, MgS and mixtures thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a group consisting of quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof. The group II-VI compounds may further contain group Ill metals.

The group III-V compounds may be selected from the group consisting of binary compounds selected from the group consisting of GaN, GaP, GaAs, GaSb, AlN, AlP, AlAs, AlSb, InN, InP, InAs, InSb, and mixtures thereof; ternary compounds selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The group III-V compounds may further contain group II metals (e.g., InZnP).

The group IV-VI compounds may be selected from the group consisting of binary compounds selected from the group consisting of SnS, SnSe, SnTe, PbS, PbSe, PbTe and mixtures thereof; ternary compounds selected from the group consisting of SnSeS, SnSeTe, SnSTe, PbSeS, PbSeTe, PbSTe, SnPbS, SnPbSe, SnPbTe and mixtures thereof; and quaternary compounds selected from the group consisting of SnPbSSe, SnPbSeTe, SnPbSTe and mixtures thereof.

The group IV elements or compounds may be selected from the group consisting of a single element compound selected from the group consisting of Si, Ge and/or one or more (e.g., any suitable) combinations thereof; and a binary compound selected from the group consisting of SiC, SiGe and/or one or more (e.g., any suitable) combinations thereof.

The group I-III-VI compounds may be selected from among CuInSe₂, CuInS₂, CuInGaSe and CuInGaS.

The group II-III-VI compounds may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe and/or one or more (e.g., any suitable) combinations thereof.

The group I-II-IV-VI compounds may be selected from amongst CuZnSnSe and CuZnSnS.

The quantum dots may be cadmium-free. The quantum dots may include semiconductor nanocrystals based on group III-V compounds including indium and phosphorus. The group III-V compounds may further contain zinc. The quantum dots may include semiconductor nanocrystals based on the group II-VI compounds including chalcogen elements (e.g., sulfur, selenium, tellurium, and/or one or more (e.g., any suitable) combinations thereof) and zinc.

In quantum dots, the aforementioned binary, ternary and/or quaternary compounds may exist within the particle at a uniform (e.g., substantially uniform) concentration, or may exist within the same (e.g., substantially the same) particle with the concentration distribution partially divided into different states. Additionally, one quantum dot may have a core/shell structure around (e.g., surrounding) another quantum dot. The interface between the core and the shell may have a concentration gradient in which the concentration of elements present in the shell decreases toward the center. For example, the interface between the core and shell may have a concentration gradient in which the concentration of elements present in the shell decreases or continuously decreases in a direction toward the center.

In one or more embodiments, the quantum dots may have a core-shell structure including a core including the aforementioned nanocrystals and a shell around (e.g., surrounding) the core. The shell of the quantum dots may serve as a protective layer to maintain semiconductor properties by preventing or reducing chemical modification of the core and/or as a charging layer to impart electrophoretic properties to the quantum dots. The shell may be single-layered or multi-layered. The interface between the core and the shell may have a concentration gradient in which the concentration of elements present in the shell decreases toward the center. Examples of shells of quantum dots include oxides of metals or non-metals, semiconductor compounds, and/or one or more (e.g., any suitable) combinations thereof.

The oxides of metals or nonmetals may be binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄.

Semiconductor compounds include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like.

The quantum dots may have a full width of half maximum of an emission wavelength spectrum of about 45 nm or less, about 40 nm or less, or about 30 nm or less, and may improve color purity or color reproducibility in this range. Additionally, because the light emitted by these quantum dots is emitted in all directions, the viewing angle may be improved.

The quantum dots may have shell materials and core materials with different energy band gaps. For example, the energy band gap of the shell material may be larger or smaller than that of the core material. The quantum dots may have multilayer shells. In a multilayer shell, the energy band gap of the outer layers may be larger than that of the inner layers (i.e., the layers closer to the core). In a multilayer shell, the energy band gap of the outer layer may be smaller than the energy band gap of the inner layer.

The shape of the quantum dots is not particularly restricted and may include one or more suitable shapes. For example, the shape of the quantum dots may include a sphere, a polyhedron, a pyramid, a multipod, a square, a cuboid, a nanotube, a nanorod, a nanowire, a nanosheet, and/or a (e.g., any suitable) combination thereof.

The quantum dots may include organic ligands (e.g., having hydrophobic moieties and/or hydrophilic moieties). Organic ligand moieties may be bound to the surface of the quantum dots. The organic ligands may include RCOOH, RNH₂, R₂NH, R₃N, RSH, R₃PO, R₃P, ROH, RCOOR, RPO(OH)₂, RHPOOH, R₂POOH, and/or one or more (e.g., any suitable) combinations thereof. Here, R may each independently be a substituted or unsubstituted aliphatic hydrocarbon group having a carbon number of C₃ to C₄₀ (e.g., C₅ or more and C₂₄ or less), a substituted or unsubstituted alkenyl group, a substituted or unsubstituted aromatic hydrocarbon group having a carbon number of C₆ to C₄₀ (e.g., C₆ or more and C₂₀ or less), and/or a (e.g., any suitable) combination thereof.

Examples of organic ligands include thiol compounds such as methanethiol, ethanethiol, propanethiol, butanethiol, pentanethiol, hexanethiol, octanethiol, dodecanethiol, hexadecanethiol, octadecanethiol, and benzylthiol; amines such as methane amine, ethane amine, propan amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributyl amine, and trioctyl amine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, and trioctyl phosphine; phosphine compounds such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, and trioctylphosphine oxide, or oxide compounds thereof; diphenyl phosphine, triphenyl phosphine compounds, or oxide compounds thereof; examples thereof include C₅ to C₂₀ alkyl phosphinic acids, C₅ to C₂₀ alkyl phosphonic acids, such as hexyl phosphinic acid, octyl phosphinic acid, dodecane phosphinic acid, tetradecane phosphinic acid, hexadecane phosphinic acid, and octadecane phosphinic acid; and/or the like. The quantum dots may contain hydrophobic organic ligands alone or in a mixture of one or more. The hydrophobic organic ligand may not contain a photopolymerizable moiety (e.g., an acrylate group, a methacrylate group, and/or the like).

The first color conversion pattern 110a, the second color conversion pattern 110b, and the third color conversion pattern 110c may be partitioned or separated by the light blocking layer 130. For example, the light blocking layer 130 may be between the first color conversion pattern 110a and the second color conversion pattern 110b and/or between the second color conversion pattern 110b and the third color conversion pattern 110c. The first color conversion pattern 110a, the second color conversion pattern 110b, and the third color conversion pattern 110c may be formed, for example, by an inkjet printing process.

A second capping layer may be positioned on the color conversion layer 110 and the light blocking layer 130. The second capping layer may be positioned to cover or entirely cover the color conversion layer 110 and the light blocking layer 130, and may protect the color conversion layer 110. The second capping layer may include an inorganic insulating material such as silicon oxide, silicon nitride, or silicon oxynitride, and may have a single-layer structure or a multi-layer structure.

The filling part 300 may be positioned above the color conversion part 100. For example, the filling part 300 may be positioned on the color conversion layer 110 and the light blocking layer 130 of the color conversion part 100. A spacer 330 and an insulating layer 310 of the filling part 300 may be positioned on the color conversion layer 110 and the light blocking layer 130 of the color conversion part 100.

The spacer 330 may be positioned on the blocking layer 130. The spacer 330 may be positioned between the color conversion layers 110. The color conversion layer 110 may be positioned between adjacent spacers 330. In the case of the spacers 330 are separated, the color conversion layer 110 may be positioned between a pair of adjacent spacers 330. For example, the first color conversion pattern 110a, the second color conversion pattern 110b, and the third color conversion pattern 110c may each be positioned between a pair of adjacent spacers 330. One spacer 330 may be positioned between the first color conversion pattern 110a and the second color conversion pattern 110b, between the second color conversion pattern 110b and the third color conversion pattern 110c, and between the first color conversion pattern 110a and the third color conversion pattern 110c.

The spacer 330 may include, for example, a substituted or unsubstituted haloalkane. The term “substituted” may refer to that at least one of the hydrogen or halogen atoms of the compound is replaced with a substituent such as another halogen group, a substituted or unsubstituted ether group, a substituted or unsubstituted alkoxy group, a hydroxyl group, an alkyl group, a heteroalkyl group, or a heterocycloalkyl group. “Unsubstituted” may refer to that all of the hydrogen or halogen atoms in a compound are not substituted.

The spacer 330 may be formed concurrently (e.g., simultaneously)—for example, through one fine metal mask FMM. For example, a substituted or unsubstituted haloalkane may be arranged through a fine metal mask on a light blocking layer 130 to form a spacer 330.

An insulating layer 310 may be positioned on the blocking layer 130. The insulating layer 310 may be positioned on the light blocking layer 130 and the color conversion layer 110. The insulating layer 310 may be in contact with the spacer 330. The insulating layer 310 may cover the spacer 330. For example, the insulating layer 310 may be positioned on the light blocking layer 130 and the color conversion layer 110 so as to be in contact with the upper surface and side surfaces of the spacer 330.

The refractive index of the spacer 330 may be smaller than the refractive index of the insulating layer 310. Some of the light emitted from the color conversion layer 110 may reach an area where a color filter layer 230 described in more detail later overlaps, depending on the angle of incidence. In this case, light reaching the area where the color filter layer 230 overlaps may not pass through the color filter layer 230 and may be absorbed by the color filter layer 230. Therefore, the amount of light emitted to the outside may be reduced. However, because the refractive index of the spacer 330 is smaller than the refractive index of the insulating layer 310, light may be totally reflected on the surface of the spacer 330. Accordingly, the amount of light reaching the area where the color filter layers 230 overlap may decrease, and the amount of light reaching the area where the color filter layers 230 do not overlap may increase. Therefore, the efficiency of light emitted to the outside may be improved, and visibility in the display area may be improved.

In one or more embodiments, the refractive index of the spacer 330 may be from about 0.5 to about 1.5, from about 1.0 to about 1.5, from about 1.2 to about 1.5, or from about 1.2 to about 1.4. In the refractive index range, the refractive index of the spacer 330 may be smaller than the refractive index of the insulating layer 310. Accordingly, total reflection may occur on the surface of the spacer 330. Therefore, the light efficiency may be improved and the visibility in the display area may be improved.

In one or more embodiments, the spacer 330 may be around (e.g., surround) the color conversion layer 110 in a planar manner. Here, the plane may be a plane parallel to the upper substrate 210. The spacer 330 may be around (e.g., surround) all of the first color conversion pattern 110a, the second color conversion pattern 110b, and the third color conversion pattern 110c on a plane. For example, the spacer 330 may be positioned along the light blocking layer 130 around (e.g., surrounding) the color conversion layer 110 and on the light blocking layer 130, and the spacer 330 may be around (e.g., surround) the color conversion layer 110 in a planar manner. Accordingly, the amount of light totally reflected by the spacer 330 may increase.

Referring to FIG. 3, the center of the light blocking layer 130 between openings OP adjacent to each other in a width direction (which hereinafter may be referred to as the first direction) may be aligned with the center of the spacer 330 between openings OP adjacent to each other in the width direction. Here, “width direction” may refer to the direction toward adjacent openings OP. For example, “width direction” may refer to the direction from one edge of the blocking layer 130 and the spacer 330 between adjacent openings OP to the opposite edge. For example, the center in the width direction of the light blocking layer 130 between the first opening OPa and the second opening OPb may overlap the center in the width direction of the spacer 330 between the first opening OPa and the second opening OPb. The center of the light blocking layer 130 in the width direction between the second opening OPb and the third opening OPc may overlap the center of the spacer 330 in the width direction between the second opening OPb and the third opening OPc. The center of the light blocking layer 130 in the width direction between the first opening OPa and the third opening OPc may overlap with the center of the spacer 330 in the width direction between the first opening OPa and the third opening OPc.

The lower surface of the spacer 330 may be in contact with the upper surface of the light blocking layer 130. The spacer 330 may include a contact surface that contacts the upper surface of the light blocking layer 130, and a width w130 of the upper surface of the light blocking layer 130 may be greater than or equal to a width w330 of the contact surface of the spacer 330. The entire contact surface of the spacer 330 may overlap with the upper surface of the spacer 330 which is greater than or equal to the width w330 of the contact surface of the spacer 330. The width w330 of the contact surface of the spacer 330 may be equal to or smaller than the shortest distance between adjacent openings OP with the light blocking layer 130 in between. For example, the width w330 of the contact surface of the spacer 330 may be equal to or smaller than the shortest distance between the first opening OPa and the second opening OPb, the shortest distance between the second opening OPb and the third opening OPc, and the shortest distance between the first opening OPa and the third opening OPc.

Here, “width of the upper surface” and “width of the upper surface w130” may refer to the shortest distance in the width direction of the upper surface of the light blocking layer 130. For example, it may refer to the shortest distance between adjacent openings OP (e.g., the first opening OPa and the second opening OPb, the second opening OPb and the third opening OPc, and the first opening OPa and the third opening OPc) with the light blocking layer 130 in between. Here, “width of the contact surface” and “width of the contact surface w330” may refer to the shortest distance in the width direction of the contact surface of the spacer 330. For example, it may refer to the shortest distance between the insulating layer 310 in contact with both sides (e.g., opposite sides) of the spacer 330.

The ratio of the width w330 of the contact surface of the spacer 330 to the width w130 of the upper surface of the blocking layer 130 may be about 0.5 to about 1, about 0.5 or more and less than about 1, about 0.6 to about 0.9, or about 0.7 to about 0.9. For example, the ratio of the minimum width of the contact surface of the spacer 330 to the minimum width of the upper surface of the blocking layer 130 may be within the range. Within the width ratio range, light emitted from the color conversion layer 110 to the area where the color filter layer 230 overlaps (e.g., the light blocking area) may be totally reflected on the surface of the spacer 330 and emitted to the outside. Accordingly, the light efficiency may be improved and the visibility in the display area may be improved.

The spacer 330 having a contact surface width smaller than the width of the upper surface of the light blocking layer 130 may be positioned on the light blocking layer 130 so as to share a center with the light blocking layer. The spacer 330 has a width smaller than that of the light blocking layer 130 and may be positioned on the light blocking layer 130. Additionally, both sides (e.g., opposite sides) of the spacer 330 may be positioned to be spaced and/or apart (e.g., spaced apart or separated) from both sides (e.g., opposite sides) of the light blocking layer 130 by a certain distance. Accordingly, light emitted from the second color conversion pattern 110 may be reflected (for example, in the direction of the arrow in FIG. 3) through the spacer 330 and emitted to a position where the second color filter pattern 230b does not overlap. For example, the spacer 330 is positioned to be around (e.g., surround) the second color conversion pattern 110b on a plane, so that light emitted from the second color conversion pattern 110b to one or more suitable locations in an area where the second color filter pattern 230b described in more detail later overlaps may be totally reflected. Therefore, the light efficiency may be further improved, and the visibility in the display area may be further improved. Although FIG. 3 illustrates an enlarged view of the area of the second color conversion pattern 110b and the second color filter pattern 230b of FIG. 2, the structure described with reference to FIG. 3 may be substantially equally (e.g., equally) applied to the area of the first color conversion pattern 110a and the first color filter pattern 230a, and the area of the third color conversion pattern 110c and the third color filter pattern 230c.

In one or more embodiments, the spacer 330 may have a contact surface that contacts the blocking layer 130 and a surface that protrudes from the blocking layer 130 (e.g., a protruding surface). For example, the upper surface of the spacer 330 may protrude from the upper surface of the light blocking layer 130.

A protruding surface of the spacer 330 may include a flat surface. The protruding surface of the spacer 330 may have a flat surface shape. For example, the protruding surface of the spacer 330 may have a square shape. When the protruding surface of the spacer 330 has a rectangular plane, the spacer 330 may have an approximately hexahedral shape. Accordingly, light that comes into contact with the surface (e.g., side) of the spacer 330 and is totally reflected may be totally reflected in a certain direction without being diffusely reflected.

The color filter part 200 may be positioned above the filling part 300. For example, the color filter part 200 may be positioned on the insulating layer 310 of the filling part 300. The color filter part 200 may include a refractive layer 250 and the color filter layer 230 and the refractive layer 250 and the color filter layer 230 of the color filter part 200 may be positioned on the insulating layer 310 of the filling part 300.

The refractive layer 250 may be positioned on the insulating layer 310. The refractive layer 250 may be positioned to overlap at least a portion of or the entire upper substrate 210 and color filter layer 230 described in more detail later. The refractive layer 250 may cover the color filter layer 230 and protect the color filter layer 230. Additionally, the refractive layer 250 may adjust the light path so that light passing through the color conversion layer 110 and the filling part 300 is directed to an area where the color filter layer 230 does not overlap. The refractive layer 250 may have a lower refractive index than the layers positioned above and below the refractive layer 250. The refractive layer 250 may include an organic insulating material such as an acrylic polymer.

The color filter layer 230 may be positioned on the refractive layer 250. The color filter layer 230 may include the first color filter pattern 230a, the second color filter pattern 230b, and the third color filter pattern 230c that allow light of different wavelengths to pass through. The first color filter pattern 230a, the second color filter pattern 230b, and the third color filter pattern 230c may correspond to the first color conversion pattern 110a, the second color conversion pattern 110b, and the third color conversion pattern 110c of the color conversion part 100, respectively. The first color filter pattern 230a, the second color filter pattern 230b, and the third color filter pattern 230c may overlap the first opening OPa, the second opening OPb, and the third opening OPc of the color conversion part 100, respectively.

The first color filter pattern 230a, the second color filter pattern 230b, and the third color filter pattern 230c may each transmit light of different wavelengths and absorb light of the remaining wavelengths. For example, the first color filter pattern 230a may be configured to transmit light of the first wavelength and absorb light of the remaining wavelengths (e.g., wavelengths not including the first wavelength). The second color filter pattern 230b may be configured to transmit light of the second wavelength and absorb light of the remaining wavelengths (e.g., wavelengths not including the second wavelength). The third color filter pattern 230c may be configured to transmit light of the third wavelength and absorb light of the remaining wavelengths (e.g., wavelengths not including the third wavelength). Accordingly, the purity of light emitted from the display area (e.g., light of the first wavelength, light of the second wavelength, and light of the third wavelength) may be increased. The light of the first wavelength, the light of the second wavelength, and the light of the third wavelength may be red light, green light, and blue light, respectively.

Different color filter patterns 230a, 230b, 230c may overlap each other to form a light blocking area. At least two selected from among the first color filter pattern 230a, the second color filter pattern 230b, and the third color filter pattern 230c may overlap each other to form a light blocking area. For example, the first color filter pattern 230a, the second color filter pattern 230b, and the third color filter pattern 230c may all overlap to form a light blocking area, and two selected from among the first color filter pattern 230a, the second color filter pattern 230b, and the third color filter pattern 230c may also overlap to form a light blocking area. In FIG. 2, the third color filter pattern 230c, the first color filter pattern 230a, and the second color filter pattern 230b are sequentially laminated based on the upper substrate 210, but they may be laminated in a different order.

The upper substrate 210 may be positioned above the color filter layer 230. The upper substrate 210 may include substantially the same (e.g., then same) material as the lower substrate SUB. The upper substrate 210 may include a material having rigid properties such as glass or a material having flexible properties such as plastic. For example, the upper substrate 210 may be a glass substrate and may also include a polymer material such as polyimide, polyamide, polyethylene terephthalate, and/or the like.

The filling part 300 may be provided as a joint that joins the display part DS and the color filter part 200. The display part DS and the color filter part 200 are joined through the filling part 300, so that the display panel 10 including both (e.g., simultaneously) a display part DS and the color filter part 200 may be manufactured.

The color filter layer 230 and the spacer 330 may be spaced and/or apart (e.g., spaced apart or separated) from each other with the insulating layer 310 therebetween. For example, the spacer 330 may be covered by the insulating layer 310, and the color filter layer 230 may be positioned on the insulating layer 310. The height of the spacer 330 (e.g., distance between an upper surface of the spacer 330 and the substrate SUB) may be lower than the height of the filling part 300 (e.g., distance between an upper surface of the filling part 300 and the substrate SUB). In the case of the height of the spacer 330 is formed to be equal to or higher than the height of the filling part 300, the insulating layer 310 may not cover the spacer 330. In this case, the contact area between the insulating layer 310 that joins the display part DS and the color filter part 200 and the color filter part 200 may be reduced. Therefore, the bonding strength between the display part DS and the color filter part 200 may be reduced. However, because the insulating layer 310 is positioned to cover the spacer 330, the contact area between the insulating layer 310 and the color filter part 200 may increase, and the bonding force between the display part DS and the color filter part 200 may be improved.

The base layer BL including the substrate SUB and the display part DS including the color conversion part 100 positioned above the base layer BL may be manufactured. The color filter part 200 including the upper substrate 210 may be manufactured independently from the display part DS. The display part DS and the color filter part 200, which are manufactured independently, may be joined through the filling part 300. For example, after forming the spacer 330 on the light blocking layer 130 of the display part DS, a material for the insulating layer 310 may be applied. Thereafter, the refractive layer 250 of the color filter part 200 may be laminated so that it comes into contact with the insulating layer 310, and then pressed and cured to manufacture the display panel 10. Although it has been stated that the display panel 10 is manufactured by bonding the independently manufactured display part DS and the color filter part 200 to the filling part 300, the display panel 10 may also be manufactured by sequentially laminating the display part DS, the filling part 300, and the color filter part 200.

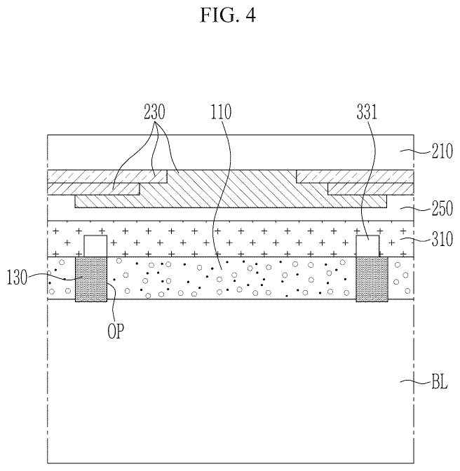

FIGS. 4 to 6 are schematic cross-sectional views each being lof an area corresponding to one pixel of a display area in a display device according to one or more embodiments.

Referring to FIGS. 4 to 6, spacers 331, 332, 333 may be positioned on a light blocking layer 130 positioned between adjacent openings in the width direction among a plurality of openings OP. For example, the spacers 331, 332, 333 may be positioned on the light blocking layer 130 positioned between a pair of adjacent openings among a plurality of openings OP. The spacers 331, 332, 333 may overlap with the light blocking layer 130 and may not overlap with the opening OP. For example, all of the spacers 331, 332, 333 may overlap with the light blocking layer 130. The structure of the regions of the color conversion layer 110 and the color filter layer 230 in FIGS. 4 to 6 may be applied to all of the first color conversion pattern 110a and the first color filter pattern 230a, the second color conversion pattern 110b and the second color filter pattern 230b, and the third color conversion pattern 110c and the third color filter pattern 230c described with reference to FIGS. 2 and 3.

Referring to FIG. 4, the blocking layer 130 and the spacer 331 may extend in a direction intersecting the width direction (hereinafter, also referred to as the second direction). For example, the blocking layer 130 and the spacer 331 may extend in a direction intersecting the direction from the opening OP positioned on one side of the blocking layer 130 to the opening OP positioned on the other side.

A center line extending in a direction intersecting the width direction (first direction) of the contact surface of the spacer 331 may be offset from a center line extending in a second direction of the upper surface of the light blocking layer 130. For example, the first direction (e.g., width direction) may intersect the second direction and the second direction may be normal (e.g., perpendicular) to the first direction (e.g., the width direction). This may refer to that the first direction runs horizontally (width-wise), while the second direction runs vertically (height-wise), forming a 90-degree angle with each other. Here, “offset” refers to that they are not aligned but are spaced and/or apart (e.g., spaced apart or separated) from each other by a certain distance. For example, the center line extending in the second direction of the contact surface of the spacer 331 may not coincide with the center line extending in the second direction of the upper surface of the light blocking layer 130. Additionally, the center line extending in the second direction of the contact surface of the spacer 331 may be spaced and/or apart (e.g., spaced apart or separated) from the center line extending in the second direction of the upper surface of the light blocking layer 130 by a set or predetermined distance in the first direction.

The spacer 331 and the blocking layer 130 may have edges extending in the second direction. For example, the spacer 331 and the blocking layer 130 may have edges extending in a direction intersecting the direction from the opening OP positioned on one side of the blocking layer 130 to the opening OP positioned on the other side.

Any one edge of the spacer 331 may overlap with any one edge of the light blocking layer 130. For example, the contact surface of the spacer 331 may have a smaller width in the first direction than the upper surface of the light blocking layer 130, and the center line may be offset in the second direction. Accordingly, one edge of the contact surface of the spacer 331 extending in the second direction may overlap one edge of the upper surface of the light blocking layer 130 extending in the second direction, and the center line extending in the second direction may be offset.

One edge of the contact surface of the spacer 331 and the upper surface of the light blocking layer 130 overlap, and the center lines of the contact surface of the spacer 331 and the upper surface of the light blocking layer 130 are offset, so that the spacer 331 may be positioned to be biased toward one side of the light blocking layer 130. Accordingly, even if the color conversion layers 110 positioned on both sides (e.g., opposite sides) of the spacer 331 emit light having different wavelengths, the spacer 331 may be positioned so as to be biased toward the color conversion layer 110 that emits light having a relatively shorter wavelength. Accordingly, even if the color conversion layers 110 positioned on both sides (e.g., opposite sides) of the spacer 331 emit light of different wavelengths, the light may be totally reflected from the surface of the spacer 331 to an area where the color filter layers 230 do not overlap.

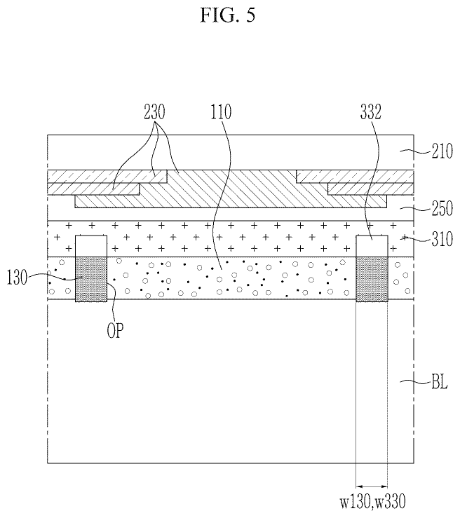

Referring to FIG. 5, the blocking layer 130 and the spacer 332 may have a pair of edges extending in the second direction. For example, the spacer 332 and the blocking layer 130 may have a pair of edges extending in a direction intersecting the direction from the opening OP positioned on one side of the blocking layer 130 to the opening OP positioned on the other side.

A pair of edges extending in the second direction of the contact surface of the spacer 332 may overlap a pair of edges extending in the second direction of the upper surface of the light blocking layer 130. The contact surface of the spacer 332 may have the same width as the upper surface of the light blocking layer 130 in the first direction, and the center lines in the direction intersecting the width direction may be aligned. For example, the width w330 of the contact surface of the spacer 332 may be the same as the width w130 of the upper surface of the light blocking layer 130, and the center lines in the second direction may overlap.

A pair of edges extending in the second direction of the contact surface of the spacer 332 may overlap a pair of edges extending in the second direction of the upper surface of the light blocking layer 130. For example, the width w330 of the contact surface of the spacer 332 may be the same as the width w130 of the upper surface of the light blocking layer 130.

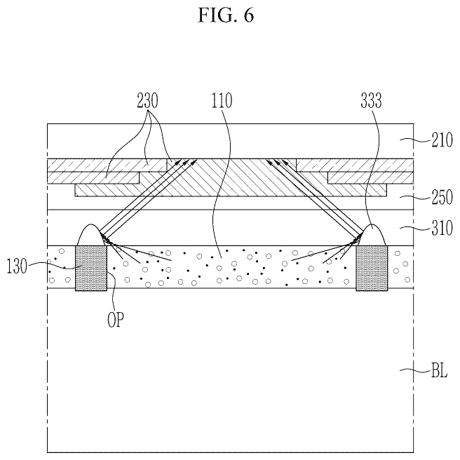

Referring to FIG. 6, the spacer 333 may have a contact surface that contacts the light blocking layer 130 and a surface that protrudes from the light blocking layer 130. For example, the upper surface of the spacer 333 may protrude from the upper surface of the light blocking layer 130.

The protruding surface of the spacer 333 may include a curved surface. The protruding surface of the spacer 333 may have a circular or elliptical planar shape. For example, the spacer 333 may have a roughly hemispherical or oval hemisphere shape. Accordingly, among the light emitted from the color conversion layer 110, light having a small angle with respect to the direction normal (e.g., perpendicular) to the upper surface of the color conversion layer 110 may be emitted to an area where the color filter layer 230 does not overlap.

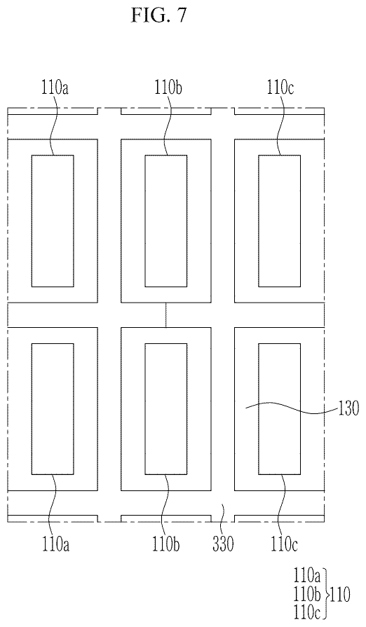

FIGS. 7 to 11 are schematic plan views each being of a display area in a display device according to one or more embodiments.

Referring to FIGS. 7 to 11, the light blocking layer 130 and the spacer 330 may overlap on a plane. The spacer 330 may overlap the light blocking layer 130 while having a width smaller than that of the light blocking layer 130. The light blocking layer 130 may be around (e.g., surround) the first color conversion pattern 110a, 110a′, the second color conversion pattern 110b, 110b′, and the third color conversion pattern 110c, 110c′ in a plane parallel to the lower substrate (e.g., in a plan view of the lower substrate). In the context of the present disclosure and unless otherwise defined, a plan view is an orthographic projection of a three-dimensional object from the position of a horizontal plane through the object. That is, it is a top-down or bottom-up view, showing the layout and spatial relationships of various elements within the object or structure. A plan view based on the z-axis direction refers to a top-down view or bottom-up, as if looking directly down onto the surface from above. In this context, the z-axis direction is the direction perpendicular or normal to the plane defined by the x-axis direction and the y-axis direction.

The spacer 330 positioned on the light blocking layer 130 may be around (e.g., surround) the first color conversion pattern 110a, 110a′, the second color conversion pattern 110b, 110b′, and the third color conversion pattern 110c, 110c′ at least partially on a plane parallel to the lower substrate.

FIG. 7 is a schematic plan drawing of the plan view of FIG. 2. Referring to FIG. 7, the spacer 330 may overlap the light blocking layer 130 on a plane while having a width smaller than that of the light blocking layer 130. For example, the width of the spacer 330 in both (e.g., simultaneously) the width direction and the direction crossing the width direction may be smaller than that of the light blocking layer 130.

The spacer 330 may be formed of any connected member. For example, the spacer 330 overlaps the light blocking layer 130 on a plane as an integral, unbroken member, and the spacer 330 may be around (e.g., surround) the first color conversion pattern 110a, the second color conversion pattern 110b, and the third color conversion pattern 110c as an integral, unbroken member.

The spacer 330 formed by any of the members and may be formed through a photoresist process.

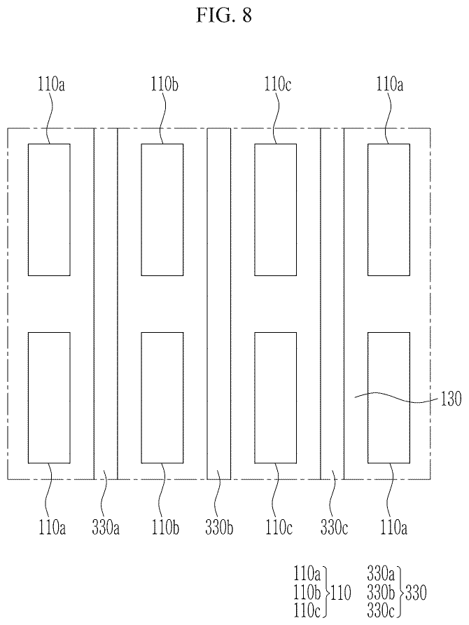

Referring to FIG. 8, the spacer 330 may be positioned only between the color conversion patterns 110a, 110b, 110c that absorb light of different wavelengths. The spacer 330 may include sub-spacers 330a, 330b, 330c that are separated from each other. The first sub-spacer 330a may be positioned between the first color conversion pattern 110a and the second color conversion pattern 110b. The second sub-spacer 330b may be positioned between the second color conversion pattern 110b and the third color conversion pattern 110c. The third sub-spacer 330c may be positioned between the first color conversion pattern 110a and the third color conversion pattern 110c.

The sub-spacers 330a, 330b, 330c may only be positioned between the color conversion patterns 110a, 110b, 110c that absorb light of different wavelengths. For example, the first sub-spacer 330a may be positioned only between the first color conversion pattern 110a and the second color conversion pattern 110b. The second sub-spacer 330b may be positioned only between the second color conversion pattern 110b and the third color conversion pattern 110c. The third sub-spacer 330c may be positioned only between the first color conversion pattern 110a and the third color conversion pattern 110c.

The spacer 330 and sub-spacers 330a, 330b, 330c may not be positioned between the substantially identical or identical color conversion patterns 110a, 110b, 110c. For example, the spacer 330 may not be positioned between the first color conversion patterns 110a. The spacer 330 may not be positioned between the second color conversion patterns 110b. The spacer 330 may not be positioned between the third color conversion patterns 110c.

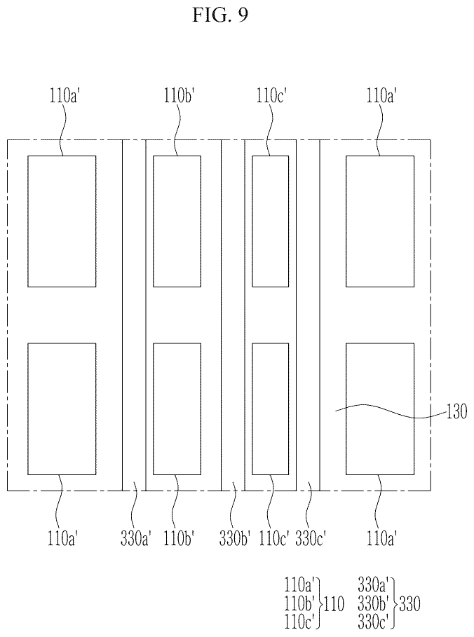

Referring to FIG. 9, the spacer 330 may include a first sub-spacer 330a′, a second sub-spacer 330b′, and a third sub-spacer 330c′.

The sub-spacers 330a′, 330b′, 330c′ may be positioned between neighboring color conversion patterns 110a′, 110b′, 110c′. The sub-spacers 330a′, 330b′, 330c′ may be positioned closer to the color conversion patterns 110a′, 110b′, 110c′ that emit light of a smaller wavelength among the light converted and emitted by the neighboring color conversion patterns 110a′, 110b′, 110c′. Light of a relatively smaller wavelength may be refracted at a larger angle even if (e.g., when) incident on a medium with the same refractive index. Accordingly, light having a relatively small wavelength among the light emitted from the color conversion patterns 110a′, 110b′, 110c′ may be incident on the spacer 330 at a small angle from the plane defined by the first direction and the second direction. In this case, if the spacer 330 is spaced far from the color conversion patterns 110a′, 110b′, 110c′, the light may not be incident on the surface of the spacer 330. However, the sub-spacers 330a′, 330b′, 330c′ are positioned closer to the color conversion patterns 110a′, 110b′, 110c′ that emit light of a smaller wavelength, so that light of a shorter wavelength may also be totally reflected through the sub-spacers 330a′, 330b′, 330c′. Therefore, the light efficiency may be improved and the visibility in the display area may be improved.

The first color conversion pattern 110a′, the second color conversion pattern 110b′, and the third color conversion pattern 110c′ may each emit light of the wavelength as described above with reference to FIG. 2. For example, the first color conversion pattern 110a′ may be configured to emit red light having a maximum emission peak wavelength of about 600 nm to about 650 nm, or about 620 nm to about 650 nm. The second color conversion pattern 110b′ may be configured to emit green light having a maximum emission peak wavelength of about 500 nm to about 550 nm, or about 510 nm to about 550 nm. The third color conversion pattern 110c′ may be configured to emit blue light having a maximum emission peak wavelength of about 380 nm to about 480 nm, or about 430 nm to about 460 nm.

The first sub-spacer 330a′ may be positioned closer to the second color conversion pattern 110b′ that emits green light than to the first color conversion pattern 110a′ that emits red light. The distance in the first direction between the first sub-spacer 330a′ and the first color conversion pattern 110a′ may be longer than the distance in the first direction between the first sub-spacer 330a′ and the second color conversion pattern 110b′. One edge extending in the second direction of the first sub-spacer 330a′ may be positioned to overlap one edge extending in the second direction of the second color conversion pattern 110b′ that emits green light. For example, the first sub-spacer 330a′ may be spaced and/or apart (e.g., spaced apart or separated) from the first color conversion pattern 110a′ in the first direction, and may not be spaced and/or apart (e.g., spaced apart or separated) from the second color conversion pattern 110b′ in the first direction.

The second sub-spacer 330b′ may be positioned closer to the third color conversion pattern 110c′ that emits blue light than to the second color conversion pattern 110b′ that emits green light. The distance in the first direction between the second sub-spacer 330b′ and the second color conversion pattern 110b′ may be longer than the distance in the first direction between the second sub-spacer 330b′ and the third color conversion pattern 110c′. One edge extending in the second direction of the second sub-spacer 330b′ may be positioned to overlap one edge extending in the second direction of the third color conversion pattern 110c′ that emits blue light. For example, the second sub-spacer 330b′ may be spaced and/or apart (e.g., spaced apart or separated) from the second color conversion pattern 110b′ in the width direction, but may not be spaced and/or apart (e.g., spaced apart or separated) from the third color conversion pattern 110c′ in the first direction.

The third sub-spacer 330c′ may be positioned closer to the third color conversion pattern 110c′ that emits blue light than to the first color conversion pattern 110a′ that emits red light. The distance in the first direction between the third sub-spacer 330c′ and the first color conversion pattern 110a′ may be longer than the distance in the first direction between the third sub-spacer 330c′ and the third color conversion pattern 110c′. One edge extending in the second direction of the third sub-spacer 330c′ may be positioned to overlap one edge extending in the second direction of the third color conversion pattern 110c′ that emits blue light. For example, the third sub-spacer 330c′ may be spaced and/or apart (e.g., spaced apart or separated) from the first color conversion pattern 110a′ in the first direction, and may not be spaced and/or apart (e.g., spaced apart or separated) from the third color conversion pattern 110c′ in the first direction.

The sub-spacers 330a′, 330b′, 330c′ spaced and/or apart (e.g., spaced apart or separated) from each other may be formed through a photoresist process.

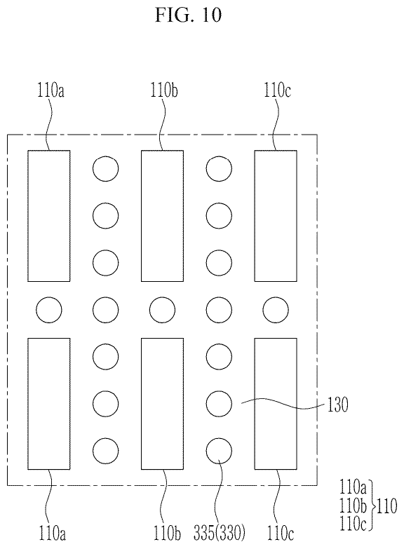

Referring to FIG. 10, the spacer 330 may include spacer units 335 that are separated from each other. The spacer units 335 may be positioned between the first color conversion pattern 110a, the second color conversion pattern 110b, and the third color conversion pattern 110c. The spacer units 335 are spaced and/or apart (e.g., spaced apart or separated) from each other and may be around (e.g., surround) the first color conversion pattern 110a, the second color conversion pattern 110b, and the third color conversion pattern 110c on a plane parallel to the lower substrate.

The spacer unit 335 may have a contact surface where the spacer unit 335 and the light blocking layer 130 come into contact and a surface protruding from the upper surface of the light blocking layer 130. The protruding surface of the spacer unit 335 may have at least one of a flat surface or a curved surface. For example, the protruding surface of the spacer unit 335 may have a circular or elliptical curved surface, and the spacer unit 335 may have an approximately hemispherical or elliptical hemispherical shape. The protruding surface of the spacer unit 335 may have a square-shaped plane, and the spacer unit 335 may have an approximately hexahedral shape. In FIG. 10, spacer units 335 having a circular shape on a plane are illustrated, but the spacer units 335 may also have a square shape.

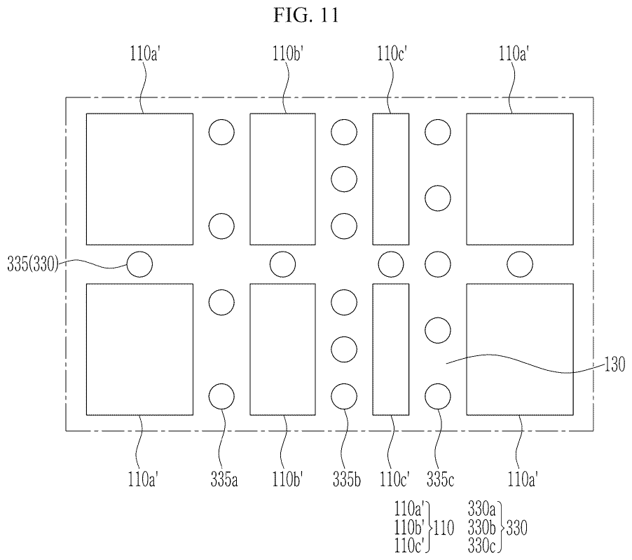

Referring to FIG. 11, the spacer unit 335 may include a first spacer unit 335a positioned between the first color conversion pattern 110a′ and the second color conversion pattern 110b′. The spacer unit 335 may include a second spacer unit 335b positioned between the second color conversion pattern 110b′ and the third color conversion pattern 110c′. The spacer unit 335 may include a third spacer unit 335c positioned between the first color conversion pattern 110a′ and the third color conversion pattern 110c′.

Different spacer units 335a, 335b, 335c may be positioned between different color conversion patterns 110a′, 110b′, 110c′. For example, the first spacer unit 335a may be positioned between the first color conversion pattern 110a′ and the second color conversion pattern 110b′. The second spacer unit 335b may be positioned between the second color conversion pattern 110b′ and the third color conversion pattern 110c′. The third spacer unit 335c may be positioned between the first color conversion pattern 110a′ and the third color conversion pattern 110c′. The spacer unit 335 may also be positioned between substantially identical or identical color conversion patterns 110a′, 110b′, 110c′.

At least two selected from among a number of first spacer units 335a, a number of second spacer units 335b, and a number of third spacer units 335c may be different from each other. For example, the number of first spacer units 335a and the number of second spacer units 335b may be different from each other. The number of second spacer units 335b and the number of third spacer units 335c may be different from each other. The number of first spacer units 335a and the number of third spacer units 335c may be different from each other. The number of first spacer units 335a, the number of second spacer units 335b, and the number of third spacer units 335c may all be different.

The number of spacer units 335 positioned between the color conversion patterns 110a′, 110b′, 110c′ that emit light with a smaller emission peak wavelength may be greater than the number of spacer units 335 positioned between the color conversion patterns 110a′, 110b′, 110c′ that emit light with a larger emission peak wavelength. The area of the color conversion patterns 110a′, 110b′, 110c′ that emit light with a smaller emission peak wavelength may be smaller than the area of the color conversion patterns 110a′, 110b′, 110c′ that emit light with a larger emission peak wavelength. The smaller the area of the color conversion patterns 110a′, 110b′, 110c′ is, the smaller the amount of light emitted from the color conversion patterns 110a′, 110b′, 110c′. Accordingly, the number of spacer units 335 desired or required to totally reflect light emitted from the smaller color conversion patterns 110a′, 110b′, 110c′ may be smaller. The number of spacer units 335 may be determined by considering the type (kind) of peak emission wavelength, thereby improving the process efficiency for manufacturing the spacer units 335.

The first color conversion pattern 110a′, the second color conversion pattern 110b′, and the third color conversion pattern 110c′ may be configured to emit red light having the largest emission peak wavelength, green light having an intermediate emission peak wavelength, and blue light having the smallest emission peak wavelength, as described with reference to FIG. 2 and FIG. 9, respectively.

The first spacer unit 335a may be formed to have the smallest number of units positioned between the first color conversion pattern 110a′ and the second color conversion pattern 110b′ that emit light having a larger peak emission wavelength than the third color conversion pattern 110c′. The second spacer unit 335b may be formed to have the largest number of units positioned between the second color conversion pattern 110b′ and the third color conversion pattern 110c′ that emit light with a smaller peak emission wavelength than the first color conversion pattern 110a′. The third spacer unit 335c may be formed to have an intermediate number of units positioned between the first color conversion pattern 110a′ that emits light with the largest emission peak wavelength and the third color conversion pattern 110c′ that emits light with the smallest emission peak wavelength.

In FIG. 11, the numbers of the first spacer unit 335a, the second spacer unit 335b, and the third spacer unit 335c are all different, taking into account the wavelengths of the color conversion patterns 110a′, 110b′, 110c′ positioned on both sides (e.g., opposite sides) of the spacer unit 335. However, the number of spacer units 335 may be determined by considering only the smaller emission peak wavelength or the larger emission wavelength among the wavelengths of the color conversion patterns 110a′, 110b′, 110c′ positioned on both sides (e.g., opposite sides). For example, considering only the smaller emission peak wavelength, the number of second spacer units 335b and the number of third spacer units 335c may be formed to be the same, and the number of first spacer units 335a may be formed to be smaller than the number of second spacer units 335b and the number of third spacer units 335c. Considering only the larger emission peak wavelength, the number of first spacer units 335a and the number of third spacer units 335c may be formed to be the same, and the number of second spacer units 335b may be formed to be greater than the number of first spacer units 335a and the number of third spacer units 335c.

The spacer units 335 spaced and/or apart (e.g., spaced apart or separated) from each other may be formed through an inkjet process. The spacer units 335 spaced and/or apart (e.g., spaced apart or separated) from each other may also be formed through a photoresist process.

A display device according to one or more embodiments may be applied to one or more suitable electronic devices. An electronic device according to one or more embodiments may include the display device, and may further include modules or devices having additional functions other than the display device.

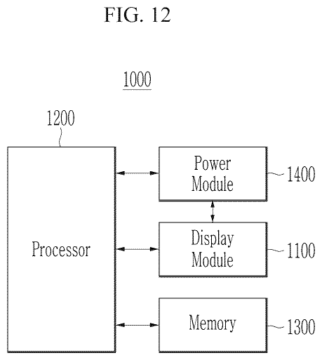

FIG. 12 is a block diagram of an electronic device according to one or more embodiments. Referring to FIG. 12, the electronic device 1000 according to one or more embodiments may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), or a controller

The memory 1300 may store data information necessary for operations of the processor 1200 or the display module 1100. When the processor 1200 executes an application stored in the memory 1300, video data signals and/or input control signals are transmitted to the display module 1100, and the display module 1100 can process the received signals to output video information through the display screen.

The power module 1400 may include a power supply module such as a power adapter or battery device, and a power conversion module that converts the power supplied by the power supply module to generate the power necessary for the operation of the electronic device 1000.

At least one of components of the electronic device 1100 may be included within the display device according to the above-described embodiments. Additionally, some of the individual modules that are functionally included within a single module may be incorporated into the display device, while others may be provided separately from the display device. For example, the display device may include the display module 1100, while the processor 1200, memory 1300, and power module 1400 may be provided in a form of other devices within the electronic device 1100 that are not part of the display device.

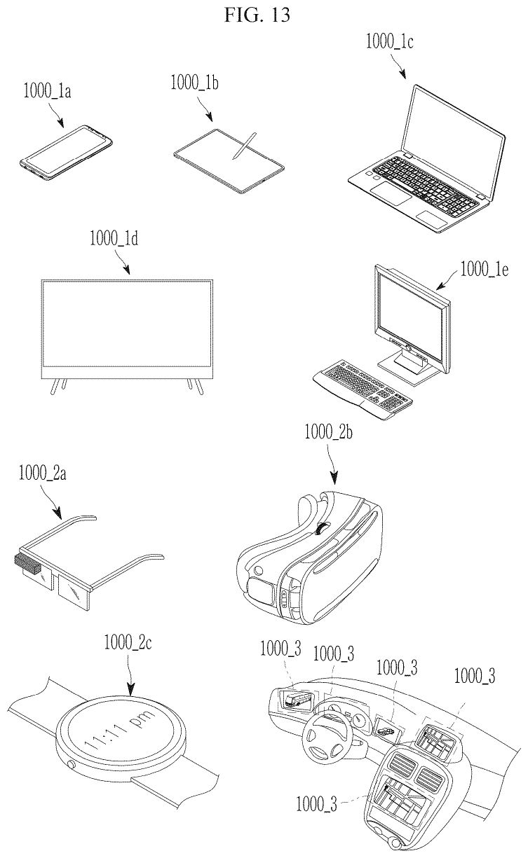

FIG. 13 shows schematic diagrams of electronic devices according to one or more suitable embodiments.

Referring to FIG. 13, one or more suitable electronic devices with the display device according to one or more embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the present disclosure have been described in more detail above, the scope of the present disclosure is not limited thereto, and one or more suitable modifications and improvements made by those skilled in the art using the basic concepts of the present disclosure defined in the following claims and equivalents thereof also fall within the scope of the present disclosure.

Reference Numerals

| | |
|---|---|
| 100: color conversion part | 110: color conversion layer |
| 110a, 110a′: first color | |
| conversion pattern | |
| 110b, 110b′: second color | |
| conversion pattern | |
| 110c, 110c′: third color | 130: light blocking layer |
| conversion pattern | |
| 200: color filter part | 210: upper substrate |
| 230: color filter layer | 230a, 230a′: first color filter pattern |
| 230b: second color filter pattern | 230c: third color filter pattern |
| 250: refracting layer | 300: filling part |
| 310: insulating layer | 330: spacer |
| 330a, 330a′: first sub-spacer | 330b, 330b′: second sub-spacer |
| 330c, 330c′: third sub-spacer | 335: spacer unit |
| 335a: first spacer unit | 335b: second spacer unit |
| 335c: third spacer unit | BL: base layer |
| DS: display part | OP: opening |
| OPa: first opening | OPb: second opening |
| OPc: third opening | |

What is claimed is:

1. A display device comprising:
a lower substrate;
a light emitting layer on the lower substrate;
an encapsulating layer on the light emitting layer;
a light blocking layer on the encapsulating layer and having a plurality of openings;
a color conversion layer on the encapsulating layer and overlapping the plurality of openings;
a spacer on the light blocking layer;
an insulating layer on the light blocking layer and the color conversion layer and contacting the spacer; and
a color filter layer on the insulating layer,
wherein a refractive index of the spacer is smaller than a refractive index of the insulating layer.

2. The display device of claim 1, wherein:
the color conversion layer is between adjacent spacers.

3. The display device of claim 1, wherein:
the spacer is around the color conversion layer in a plan view of the lower substrate.

4. The display device of claim 1, wherein:
in the spacer on the light blocking layer between a pair of openings adjacent to each other in a first direction among the plurality of openings,
the spacer comprises a contact surface that contacts an upper surface of the light blocking layer, and
a minimum width of the upper surface of the light blocking layer is greater than or equal to a minimum width of the contact surface of the spacer.

5. The display device of claim 4, wherein:
a ratio of the minimum width of the contact surface of the spacer to the minimum width of the upper surface of the light blocking layer is 0.5 to 1.

6. The display device of claim 4, wherein:
a center of the light blocking layer between the pair of openings adjacent to each other in the first direction is aligned with a center of the spacer on the light blocking layer between the pair of openings adjacent to each other in the first direction.

7. The display device of claim 4, wherein:
the light blocking layer and the spacer extend in a second direction intersecting the first direction, and
a pair of edges extending in the second direction of the contact surface of the spacer and overlapping a pair of edges extending in the second direction of the upper surface of the light blocking layer.

8. The display device of claim 4, wherein:
the light blocking layer and the spacer extend in a second direction intersecting the first direction, and
a center line extending in the second direction of the contact surface of the spacer is offset from a center line extending in the second direction of the upper surface of the light blocking layer.

9. The display device of claim 8, wherein:
the contact surface of the spacer and the upper surface of the light blocking layer have one edge that extends in the second direction and are aligned with each other in the second direction.

10. The display device of claim 1, wherein:
the spacer comprises a contact surface that contacts the light blocking layer and a surface that protrudes from the light blocking layer, and
the surface of the spacer comprises a curved surface.

11. The display device of claim 1, wherein:
the spacer comprises a contact surface that contacts the light blocking layer and a surface that protrudes from the light blocking layer, and
the surface of the spacer comprises a flat surface.

12. The display device of claim 1, wherein:
the refractive index of the spacer is in the range of 0.5 to 1.5.

13. The display device of claim 1, wherein:
the spacer and the color filter layer are spaced apart from each other with the insulating layer therebetween.

14. A display device comprising:
a lower substrate;
a light emitting layer on the lower substrate;
an encapsulating layer on the light emitting layer;
a light blocking layer on the encapsulating layer and having a plurality of openings comprising a first opening, a second opening, and a third opening;
a color conversion layer on the encapsulating layer and comprising a first color conversion pattern overlapping the first opening, a second color conversion pattern overlapping the second opening, and a third color conversion pattern overlapping the third opening;
a spacer on the blocking layer;
an insulating layer on the light blocking layer and the color conversion layer; and
a color filter layer on the insulating layer,
wherein a refractive index of the spacer is smaller than a refractive index of the insulating layer.

15. The display device of claim 14, wherein:
light is emitted from the light emitting layer, and
the first color conversion pattern, the second color conversion pattern, and the third color conversion pattern each convert the light into different colors.

16. The display device of claim 14, wherein:
the spacer is around all of the first color conversion pattern, the second color conversion pattern, and the third color conversion pattern on a plane.

17. The display device of claim 14, wherein:
the spacer comprises spacer units separated from each other, and
the spacer units are spaced apart from each other and are around the first color conversion pattern, the second color conversion pattern, and the third color conversion pattern in a plane.

18. The display device of claim 17, wherein:
the spacer unit comprises:
a first spacer unit between the first color conversion pattern and the second color conversion pattern,
a second spacer unit between the second color conversion pattern and the third color conversion pattern,
a third spacer unit between the first color conversion pattern and the third color conversion pattern, and
at least two selected from among a number of the first spacer units, a number of the second spacer units, and a number of the third spacer units are different from each other.

19. The display device of claim 14, wherein:
the spacer comprises a first sub-spacer between the first color conversion pattern and the second color conversion pattern,
a second sub-spacer between the second color conversion pattern and the third color conversion pattern, and
a third sub-spacer between the first color conversion pattern and the third color conversion pattern.

20. An electronic device, comprising:
a display device comprising:
a lower substrate;
a light emitting layer on the lower substrate;
an encapsulating layer on the light emitting layer;
a light blocking layer on the encapsulating layer and having a plurality of openings;
a color conversion layer on the encapsulating layer and overlapping the plurality of openings;
a spacer on the light blocking layer;
an insulating layer on the light blocking layer and the color conversion layer and contacting the spacer; and
a color filter layer on the insulating layer,
wherein a refractive index of the spacer is smaller than a refractive index of the insulating layer.
